(19) United States
(12) Patent Application Publication
(10) Pub. No.: US 2026/0371640 A1
(43) Pub. Date: Nov. 19, 2026

(54) METHODS AND STRUCTURES FOR CONTACT RESISTANCE REDUCTION

(71) Applicant: Taiwan Semiconductor Manufacturing Co., Ltd., Hsinchu (TW)

(72) Inventors: Chun Wei Chen, Hsinchu (TW); Chien-Chia Cheng, Hsinchu (TW); Yen Chuang, Baoshan Township (TW); Yu-Hsing Lin, Tainan City (TW)

(21) Appl. No.: 19/749,808

(22) Filed: Jul. 22, 2026

Related U.S. Application Data
(63) Continuation of application No. 18/954,105, filed on Nov. 20, 2024.

(51) Int. Cl. H10D 30/00; H10D 30/01; H10D 30/43; H10D 62/10; H10D 62/13; H10D 62/832; H10D 84/03; H10D 84/83

(52) U.S. Cl. CPC H10D 30/502; H10D 30/014; H10D 30/0191; H10D 30/024; H10D 30/43; H10D 62/121; H10D 62/151; H10D 62/832; H10D 84/038; H10D 84/834

(57) ABSTRACT

In an embodiment, a method is described that includes forming a source/drain region having a first base material composition and a first concentration of a first conductivity type dopant; removing a portion of the source/drain region having the first base material composition and the first concentration of the first conductivity type dopant to expose a contact surface; and forming a contact layer on the contact surface. The contact layer comprises a second composition and has a second concentration of the first conductivity type dopant, wherein the second concentration is greater than the first concentration for the first conductivity type dopant. A metal is deposited on the contact layer, wherein an interface between the metal and the contact layer includes a metal semiconductor alloy.

### CROSS-REFERENCE TO RELATED APPLICATIONS

This application is a continuation of U.S. patent application Ser. No. 18/954,105, filed on Nov. 20, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A, 5B, 6A, 6B, 7A, 7B, 7C, 8A, 8B, 9A, 9B, 10A, 10B, 10C, 10D, 11A, 11B, 11C, 11D, 12A, 12B, 13A, 13B, 14A, 14B, 15A, 15B, 15C, 16A, 16B, 16C, 17A, 17B, 17C, 17D, 17E, 17F, 18A, 18B, 19A, 19B, 20, 21, 22 and 23 are cross-sectional views of intermediate stages in the manufacturing of nano-FETs, in accordance with some embodiments.

FIGS. 17G, 17H, 17I and 17J are plots illustrating dopant concentrations at the contacts to the epitaxial material of the source/drain regions, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, the methods and structures described herein form a contact epitaxial layer to source/drain regions prior to silicide formation, in which the contact epitaxial layer is doped to reduce the Schottky barrier height at the interface between the contact and the material of the source/drain region. It has been determined that forming a silicide on the material of a low dopant concentration source/drain region, e.g., low dopant concentration p-type region, results in a high contact resistivity, which results from a high Schottky barrier height. The methods and structures described herein replace a portion of the low-concentration dopant source/drain material at the contact landing point with an increased dopant concentration epitaxial material. The increased dopant concentration epitaxial material at the interface of the contact and the source/drain region reduces the Schottky barrier height, and therefore reduces the contact resistance to the source/drain regions. More particularly, in some embodiments, the contact epitaxial material is deposited by chemical vapor deposition and is composed of a type IV semiconductor, such as silicon (Si), germanium (Ge), and p-type dopant for type IV semiconductors, such as boron (B or Ga). Since the dopant concentration of contact epi layer is higher than the concentration of the p-type dopant in the epitaxial material of the source/drain material, the device's contact resistivity could be reduced.

Embodiments are described below in a particular context, a die comprising nano-FETs. Various embodiments may be applied, however, to dies comprising other types of transistors (e.g., stacking transistors, or the like) in lieu of or in combination with the nano-FETs.

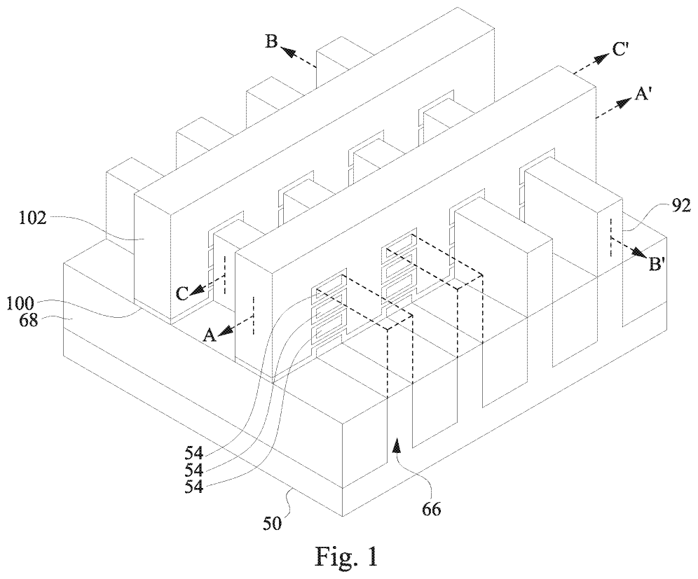

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. STI regions 68 (also referred to as STI structures or STI regions) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

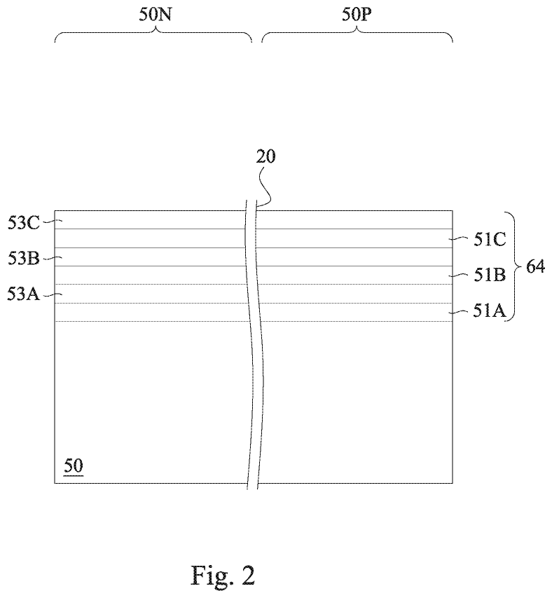

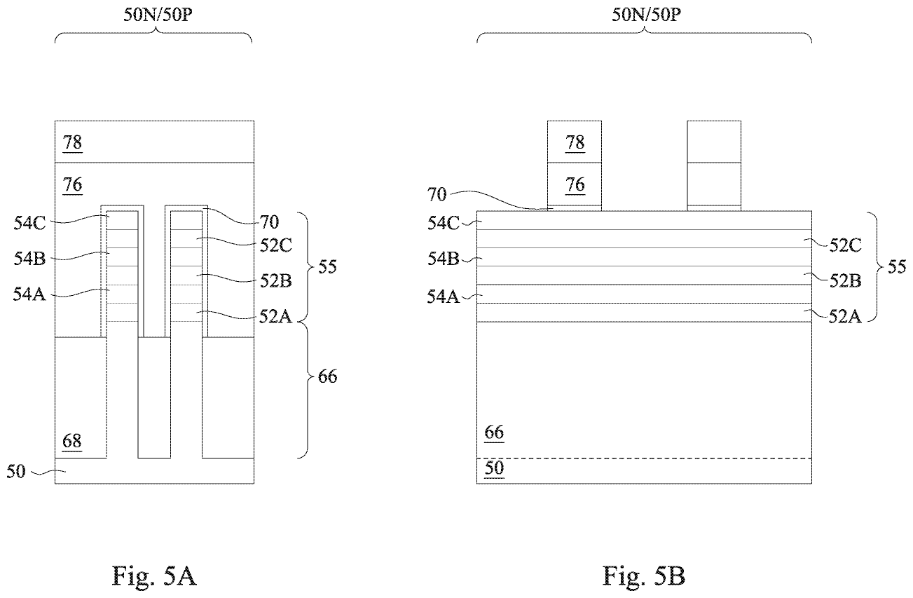

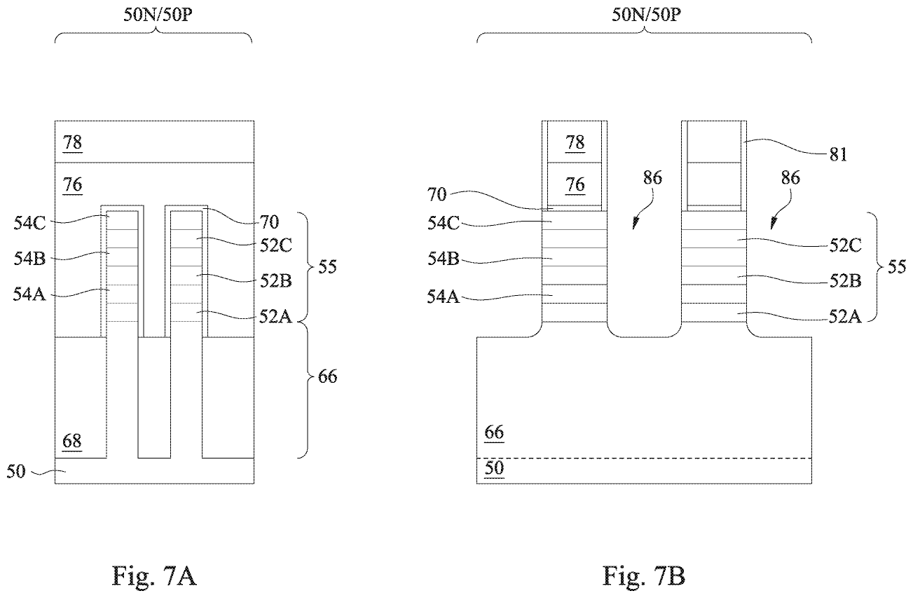

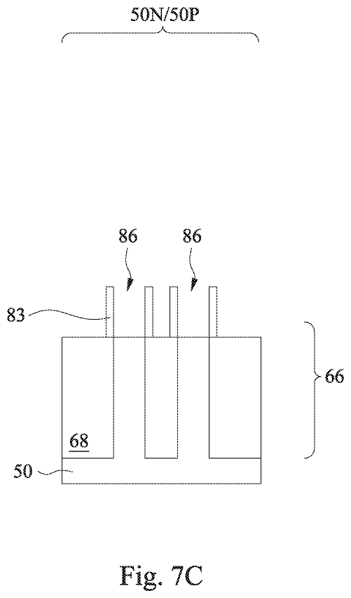

FIGS. 2 through 17F and FIGS. 18A-23 are cross-sectional views of intermediate stages in the manufacturing of nano-FETs, in accordance with some embodiments. FIGS. 2 through 5A, 6A, 7A, 8A, 9A, 10A, 11A, 12A, 13A, 14A, 15A, 15C, 16A, 17A, and 18A illustrate reference cross-section A-A′ illustrated in FIG. 1. FIGS. 5B, 6B, 7B, 8B, 9B, 10B, 10C, 10D, 11B, 12B, 13B, 14B, 15B, 16b, 17B, 17D, 17E, 17F, 18B, 19A, 19B, 20, 21, 22 and 23 illustrate reference cross-section B-B′ illustrated in FIG. 1. FIGS. 7C, 11C, 11D, 16C, 17C and 18C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or the another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

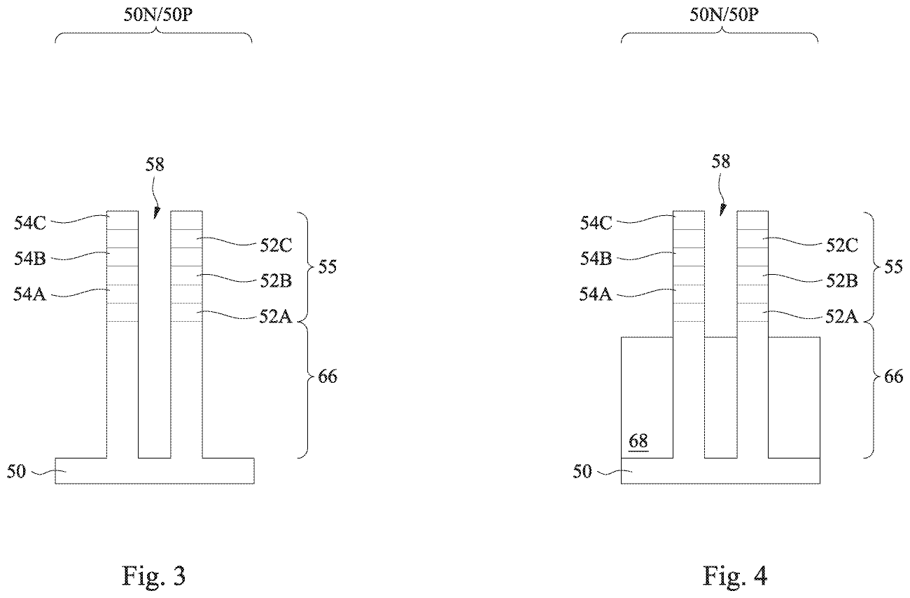

Referring now to FIG. 3, fins 66 are formed on the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates are formed over and along sidewalls of the nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

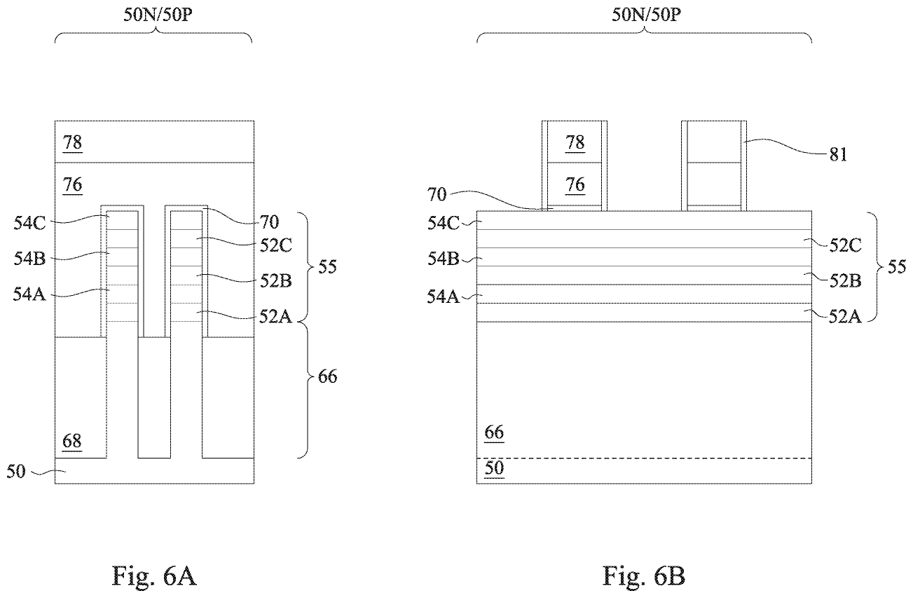

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed between the nanostructures 55, and into the portion of the substrate 50 that was previously etched to provide the fins 66, in accordance with some embodiments. Epitaxial source/drain regions will be subsequently formed in the first recesses 86. The first recesses 86 may extend through the first nanostructures 52 and the second nanostructures 54. As illustrated in FIG. 7C, top surfaces of the STI regions 68 may be level with bottom surfaces of the first recesses 86. The first recesses 86 may be formed by etching the nanostructures 55 using anisotropic etching processes, such as RIE, NBE, or the like. The gate spacers 81, the fin spacers 83, and the masks 78 mask underlying portions of the nanostructures 55 that ultimately provide the channel of the device during the etching processes used to form the first recesses 86. A single etch process or multiple etch processes may be used to etch each layer of the nanostructures 55. Timed etch processes may be used to stop the etching of the first recesses 86 after the first recesses 86 reach a desired depth.

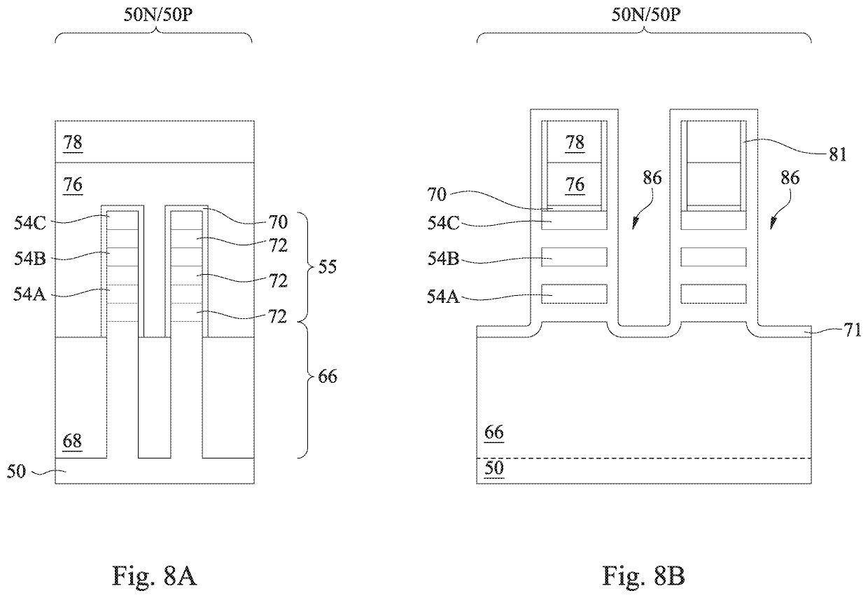

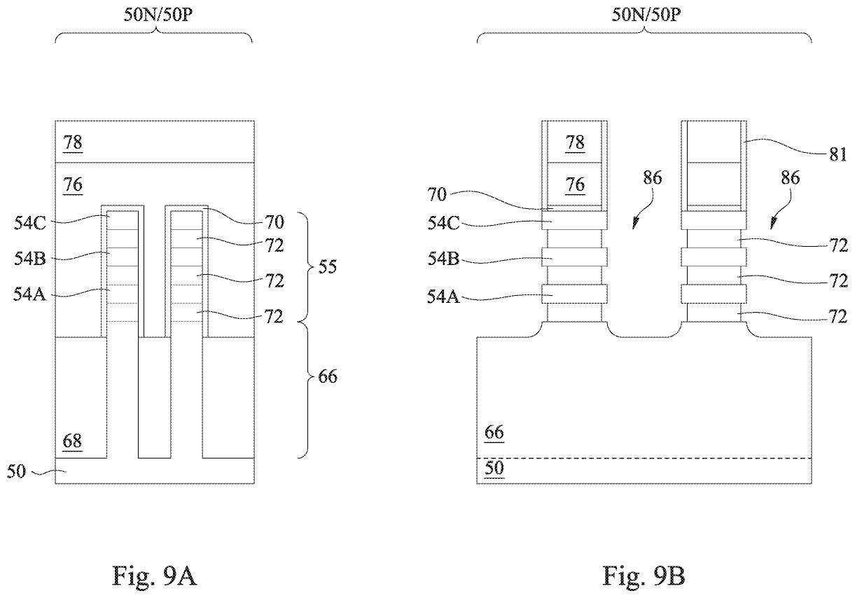

In FIGS. 8A-9B, the first nanostructures 52 are replaced with a sacrificial material 72 (also referred to as disposable oxide interposers (DOI) 72). Replacing the first nanostructures 52 may include etching away the first nanostructures 52 using a suitable etch process, such as an isotropic etch process, that is performed through the first recesses 86 as illustrated by FIGS. 8A-8B. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

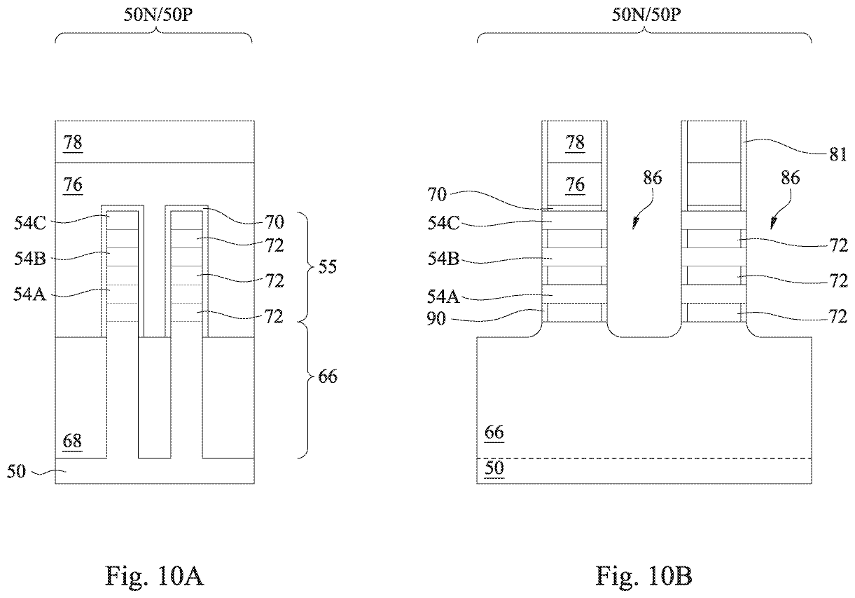

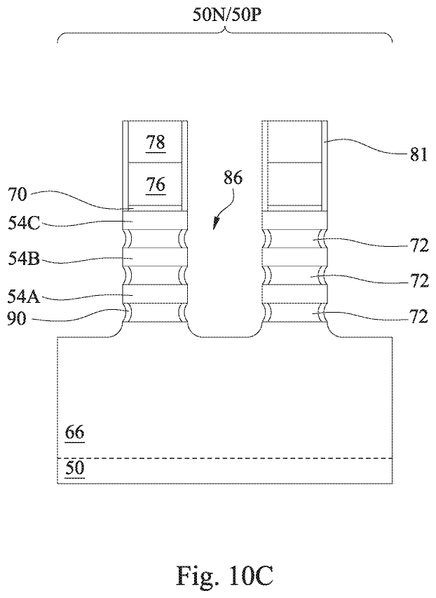

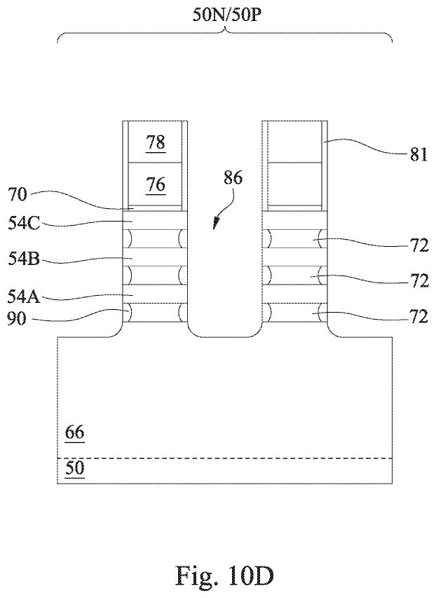

Subsequently, a sacrificial material layer 71 is deposited in the recesses 86 and spaces where the first nanostructures 52 were removed. The sacrificial material layer 71 may be deposited by a conformal deposition process, such as CVD, ALD, or the like. The sacrificial material layer may comprise an insulating material such as silicon oxide (e.g., SiO₂), or the like that can be selectively etched from the second nanostructures 54. In FIGS. 9A-9B, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIG. 9B, the sidewalls may be concave or convex (see e.g., FIG. 10C).

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect).

In FIGS. 10A and 10B, inner spacers 90 are formed in the recesses 86 on the sidewalls of the sacrificial material 72. The inner spacers 90 act as isolation features between subsequently formed source/drain regions and a gate structure. As will be discussed in greater detail below, source/drain regions will be formed in the recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 9A and 9B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 10C). Moreover, although the outer sidewalls of the inner spacers 90 are illustrated as being straight in FIG. 10B, the outer sidewalls of the inner spacers 90 may be concave or convex. As an example, FIG. 10C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 10D illustrates an embodiment in which sidewalls of the sacrificial material 72 are concave, outer sidewalls of the inner spacers 90 are straight, and the inner spacers 90 are flush with sidewalls of the second nanostructures 54.

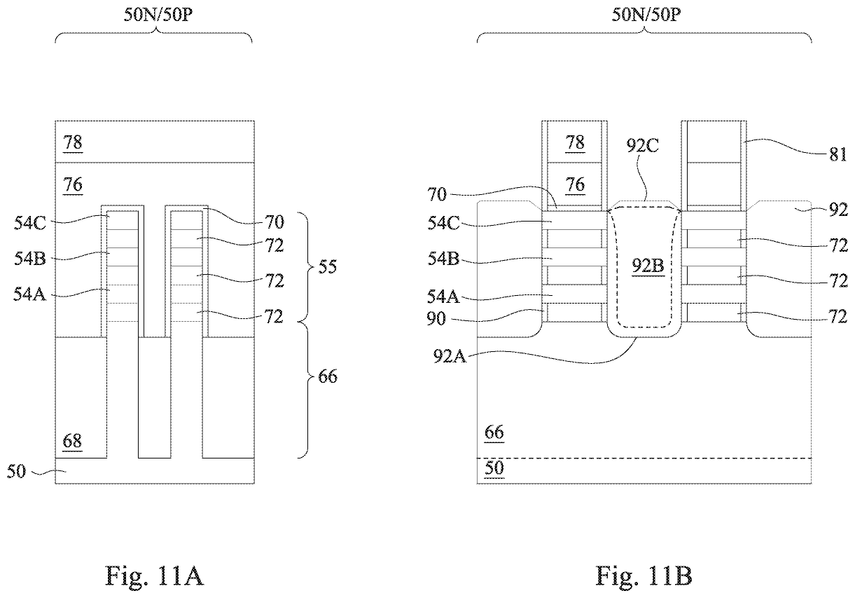

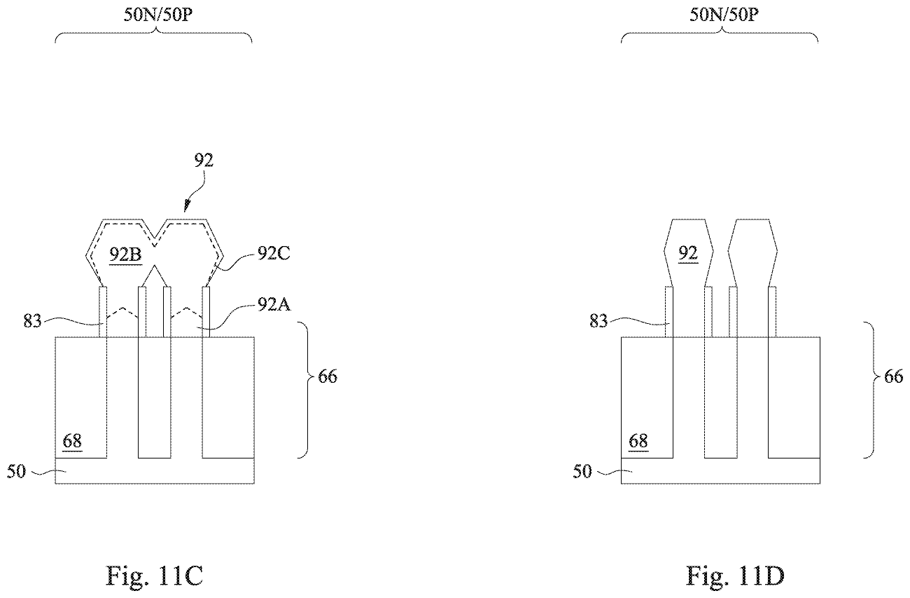

In FIGS. 11A-11D, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth. For example, the n-type or p-type dopant for the epitaxial source/drain regions 92 may be introduced with the precursor gasses during the process steps for forming the epitaxial source/drain regions 92.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 11C. In other embodiments, adjacent epitaxial source/drain regions 92 remain separated after the epitaxy process is completed as illustrated by FIG. 11D. In the embodiments illustrated in FIGS. 11C and 11D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

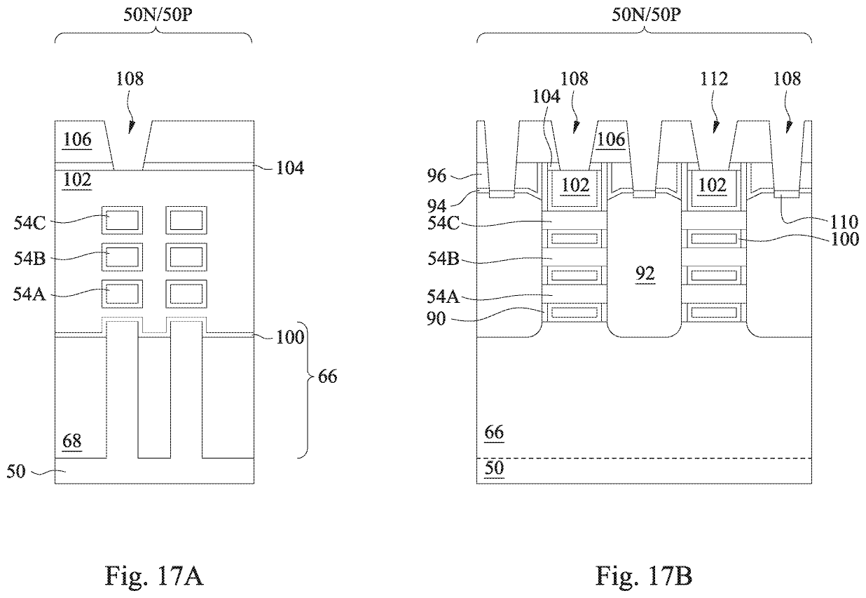

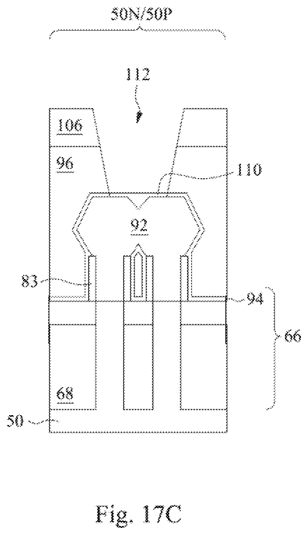

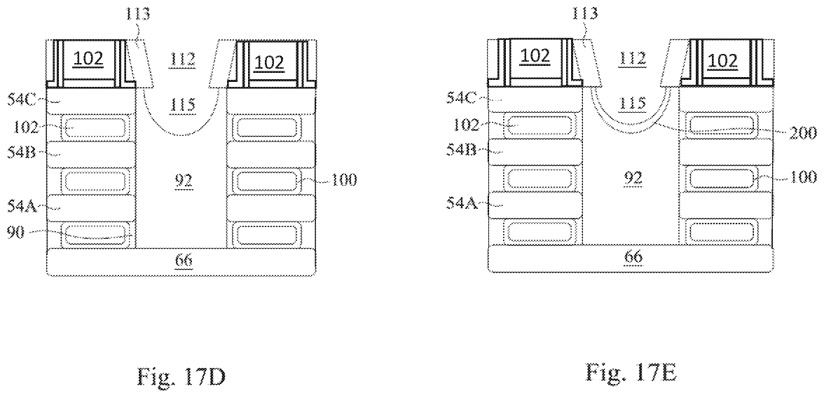

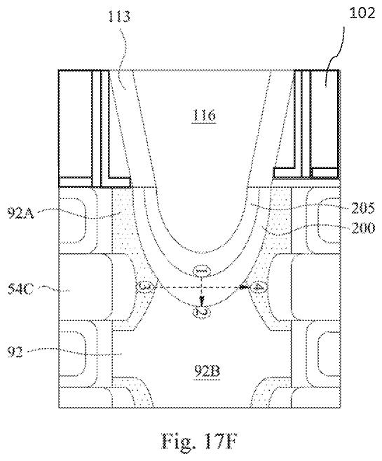

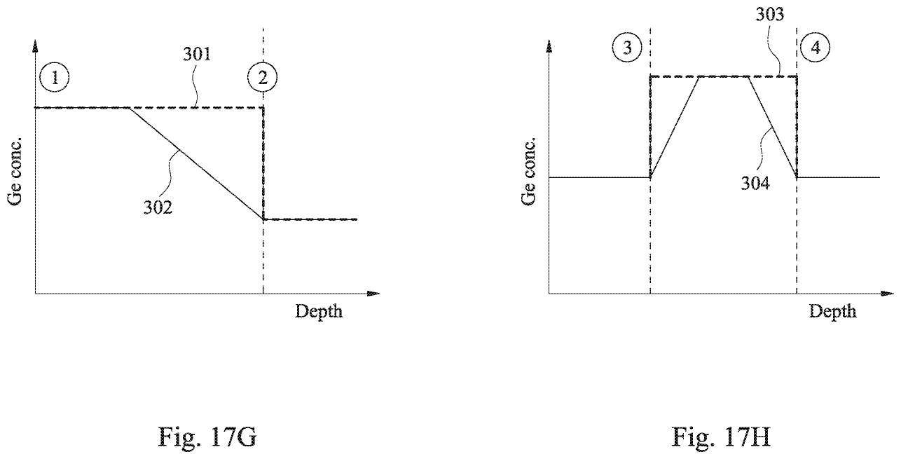

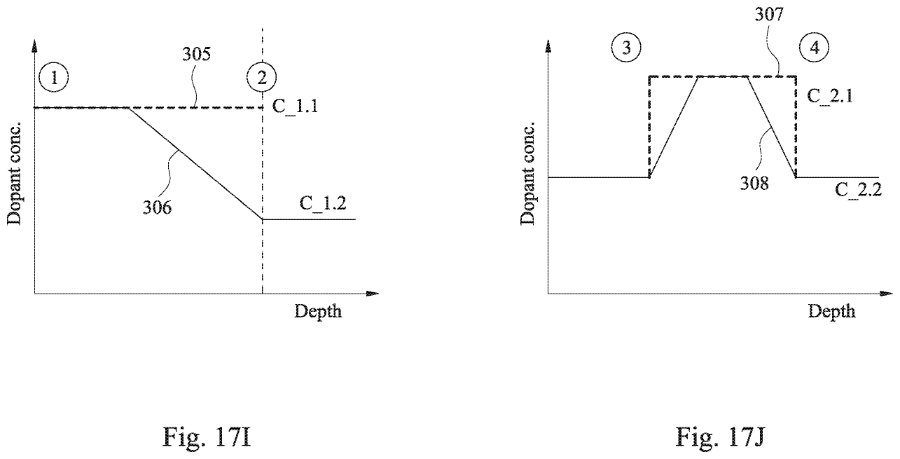

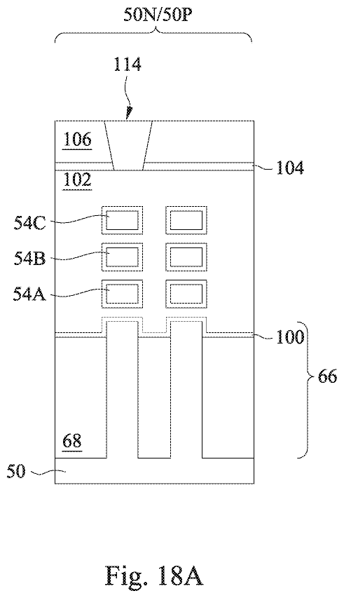

It is noted that the first semiconductor material layer 92A does not necessarily have to be deposited in a continuous layer on the sidewalls and base of the trench between the nanostructures 55. For example, the first semiconductor material layer 92A may be deposited directly onto the end portions of the second nanostructures 54 in individual portions, as depicted in FIGS. 17F, 19B, 21, 22 and 23. In one embodiment, the dopant concentration of the dopant in the first semiconductor material layer 92A may range from 8×10¹⁹ atoms/cm³ to 1×10²¹ atoms/cm³, while the second semiconductor layer 92B has a dopant concentration ranging from 1×10²¹ atoms/cm³ to 1×10²² atoms/cm³.

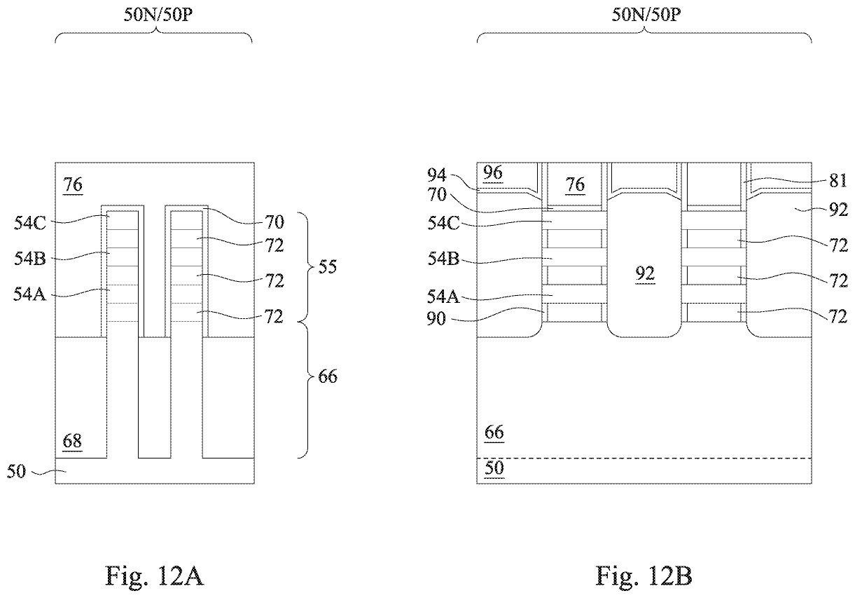

In FIGS. 12A and 12B, a first interlayer dielectric (ILD) 96 is deposited over the structure illustrated in FIGS. 11A and 11B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

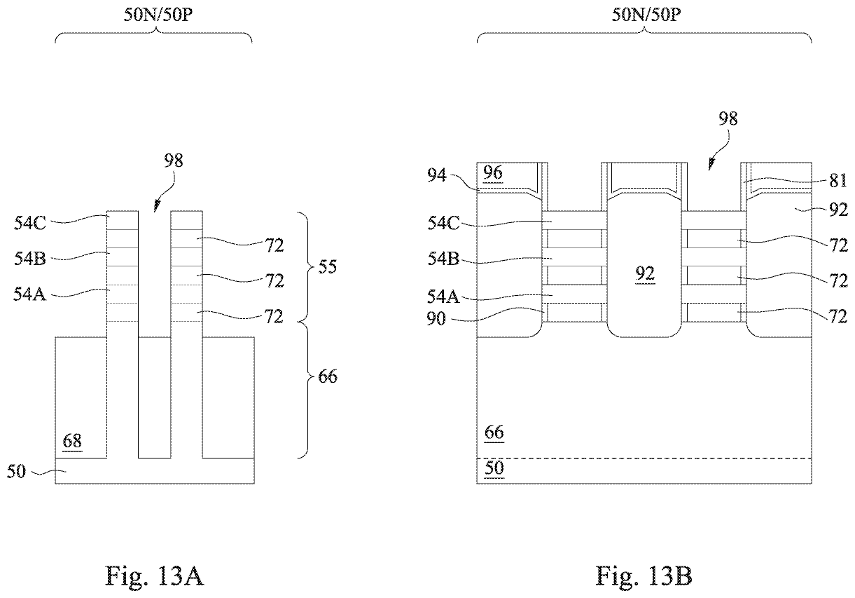

In FIGS. 13A and 13B, the dummy gates 76, and the masks 78 if present, are removed in one or more etching steps, so that second recesses 98 are formed. Portions of the dummy gate dielectrics 70 and portions of the protective liner 60 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

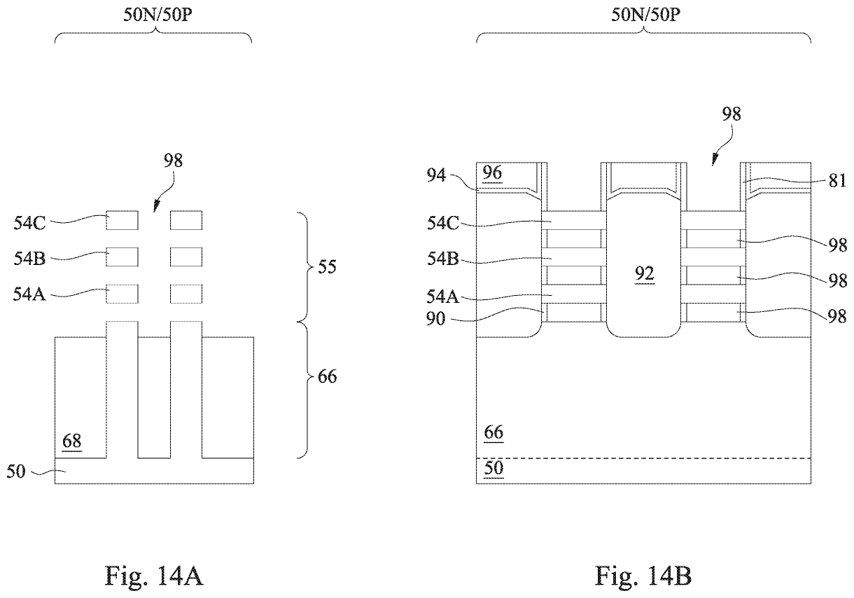

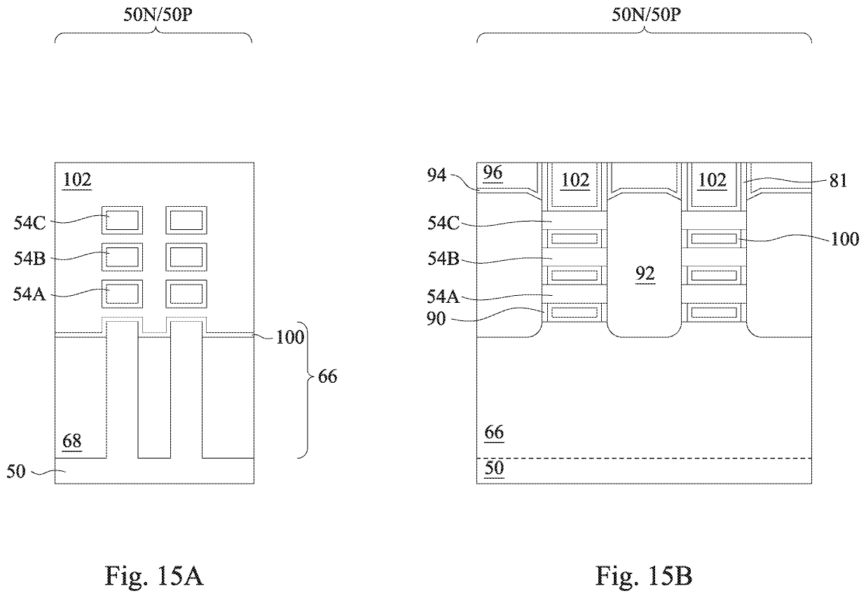

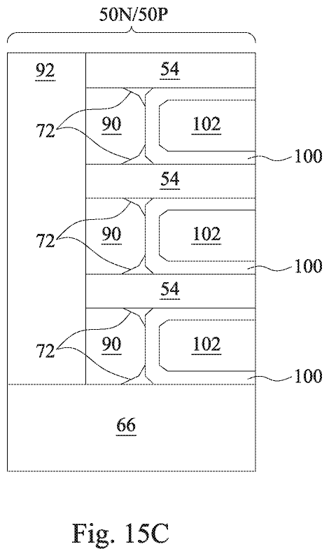

In FIGS. 14A and 14B, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98 (see e.g., FIG. 15C).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

In FIGS. 15A-15C, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 15A-15C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 15C illustrates a detailed view of various elements of FIG. 15B, including the epitaxial source/drain regions 92, the gate dielectric layers 100, the gate electrodes 102, the second nanostructures 54, and the inner spacers 90. In some embodiments, illustrated by FIG. 15C, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

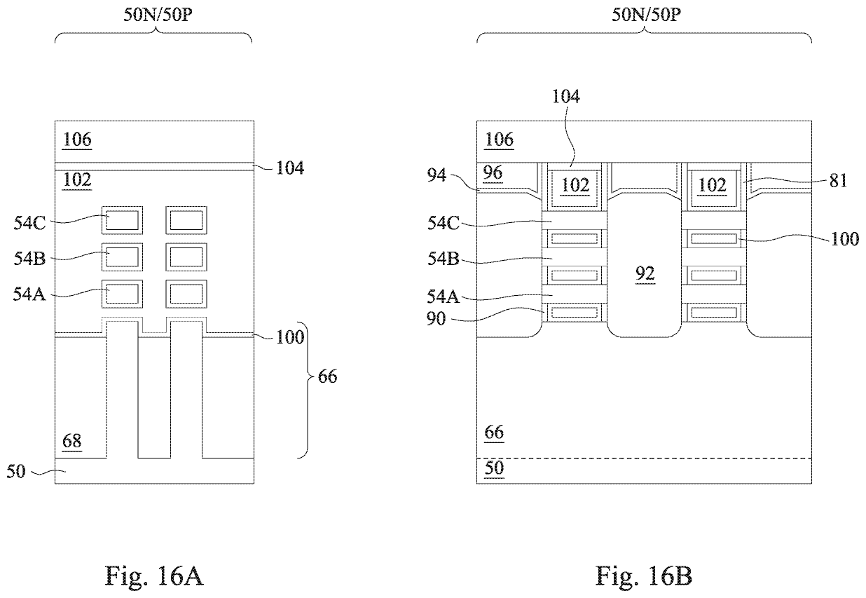

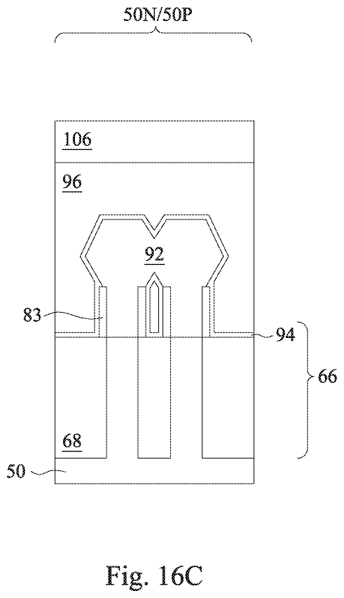

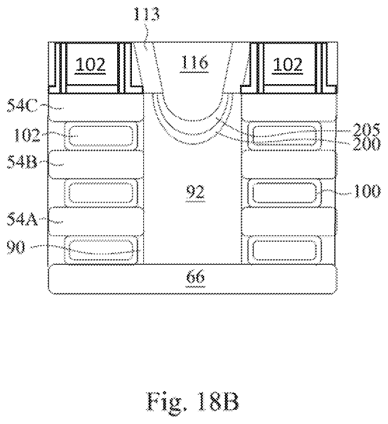

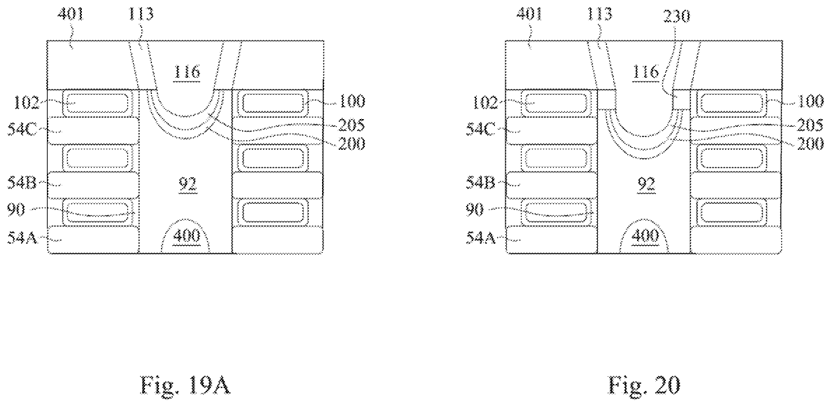

In FIGS. 16A-16C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 18A-18C) penetrate through the gate mask 104 to contact the top surface of the recessed gate electrodes 102. As will be further illustrated with reference to FIGS. 17D-17F, a contact epitaxial layer 200 may be formed on the source/drain regions 92 prior to silicide formation, in which the contact epitaxial layer is doped to reduce the Schottky barrier height at the interface between the contact and the material of the source/drain region

As further illustrated by FIGS. 16A-16C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 17A-17C, the second ILD 106, the first ILD 96, the CESL 94, and the gate masks 104 are etched to form third recesses 108 exposing surfaces of the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process.

FIGS. 17B-17C also illustrate some embodiments of forming fourth recesses 112 to the source/drain regions 92. In some embodiments, forming the fourth recesses 112 to the source/drain region 92 including an anisotropic etching process, such as RIE, NBE, or the like. In some embodiments, the fourth recesses 112 may be etched through the second ILD 106 and the first ILD 96 using a first etching process; may be etched through the gate masks 104 using a second etching process; and may then be etched through the CESL 94 using a third etching process.

In some embodiments, after forming the fourth recesses 112 through the second ILD 106, the first ILD 96 and the CESL 94 to the upper surfaces of the source/rain regions 92, a protective spacer 113 may be formed on the sidewalls of the opening provided by the fourth recesses 112. In some embodiment, the protective spacer 113 protects the sidewalls of the second ILD 106, the first ILD 96 and the CESL 94 that is exposed by forming the fourth recesses 112 during processing for applying an over etch to the upper surfaces of the source/drain regions 92, in which the over etch forms a recess 115 in the upper surface of the source/drain regions 92. In some embodiments, forming the protective spacer 113 may include depositing a conformal nitride containing layer on the vertically orientated sidewalls surfaces of the further recesses 112, and on the horizontally orientated upper surfaces of the second ILD 106, and the horizontally orientated base surface within the fourth recesses 112. The conformal nitride layer may be etched with an anisotropic etch process to remove the horizontally orientated portions leaving the vertically orientated portions to provide the protective spacer 113. In some embodiments, the anisotropic etch process may be reactive ion etching (RIE), and the protective spacer 113 may be composed of silicon nitride.

It has been determined that a silicide region formed on a low concentration of doped epitaxial material, such as source/drain regions formed of p-type doped silicon germanium, has a high contact resistance. This is because of the high Schottky barrier between the silicide formed from the metal of a contact and the low concentration p-type silicon germanium. The high contact resistance is further the result of a low carrier tunneling probability that results from the low dopant concentration of the epitaxially formed p-type doped silicon germanium.

In some embodiments, the methods and structures described herein provide a low contact resistance contact to the epitaxial source/drain regions 92 by removing a portion of the low concentration doped epitaxial material of the source/drain regions 92 at the contact landing point for the metal contact 116 (depicted in FIG. 17F) to the source/drain region 92, and epitaxially forming a high-concentration doped contact layer 200 as the contact landing point for the metal contact to the source/drain region 92. For example, silicide landed on an epitaxially formed contact layer 200 (as depicted in FIG. 17E) having a high germanium concentration and a high concentration of p-type dopant, such as boron (B) and/or gallium (Ga), results in not only a lower Schottky barrier height between silicide and the p-type epitaxial semiconductor material of the source/drain region 92, but also higher carrier tunneling probability. As a result, the contact resistivity is low.

FIG. 17D illustrates one embodiment of removing the portion of the low concentration doped epitaxial material of the source/drain regions 92 at the contact landing point forming a recess 115 in the upper surface of the source/drain regions 92. For example, the source/drain regions 92 are composed of a first composition and have a first concentration of a first conductivity type dopant. In some embodiments, the first composition of the source/drain regions 92 may include a first base material of a type IV semiconductor, such as silicon and/or germanium. For example, the first composition of the source/drain regions 92 may be silicon germanium, in which the germanium content ranges from 20 w.t % to 60 wt. %. For example, the first conductivity type for the source/drain regions 92 may be a p-type dopant, such as boron or gallium. The first concentration of the first conductivity type dopant, e.g., p-type dopant, may be present in the base material of the source/drain region in an amount that ranges from 8×10¹⁹ atoms/cm³ to 1×10²¹ atoms/cm³.

The recess 115 may be formed by an etch process that is a gaseous etch process. For example, the recess 115 may be formed prior to forming the contact layer epitaxial material, in which an HCl/Cl₂ etch is formed in the chemical vapor deposition (CVD) deposition chamber that is subsequently used for epitaxially forming the contact layer. The temperature of the etch process for forming the recess 115 may range from 300 °C to 450 °C. The pressure of the etch process for forming the recess 115 may range from 10 torr to 15o torr. It is noted that the some embodiments for the gaseous etch may include a gas etch that includes HCl with N₂ or H₂ (Carrier gas), or a gaseous etch that may include a gas etch that include Cl₂ with N₂ (Carrier gas). In some embodiments, the recess 115 may be formed using a dry etch process that includes H₂ and Cl₂ radicals using a dry etch tool, which is separate from the chemical vapor deposition (CVD) chamber. The process gasses for the dry etch process for forming the recess 115 may include H₂ and Cl₂ radicals. The pressure for the dry etch process may range from 10 mTorr to 150 mTorr. In some embodiments, the temperature for the dry etch process can range from 20 °C to 200 °C.

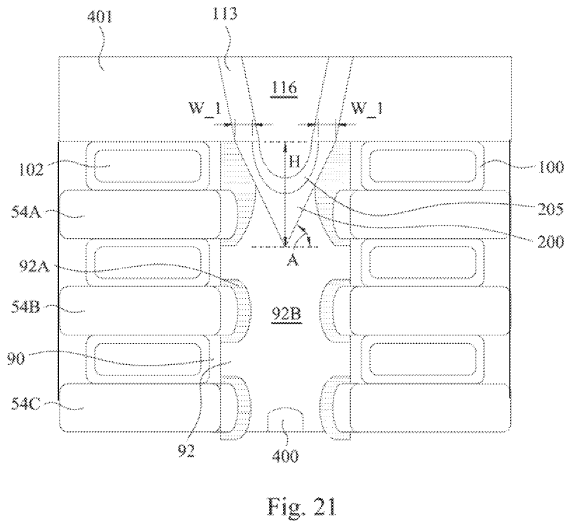

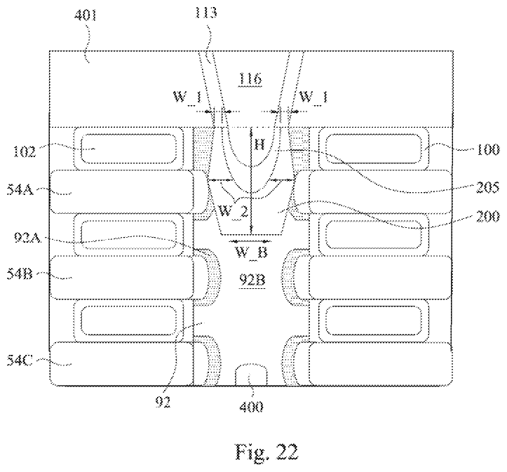

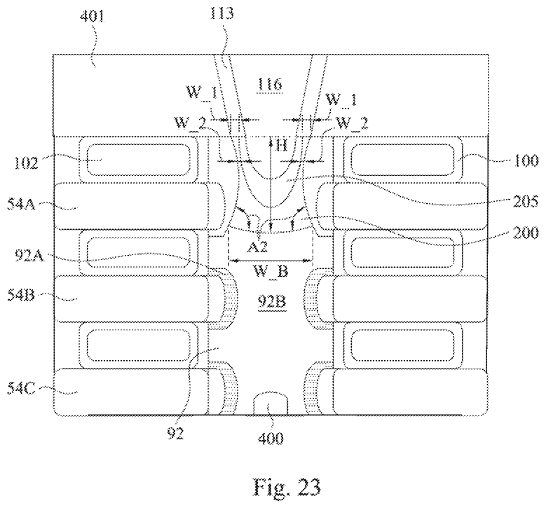

The parameters of the gas etch may be adjusted to provide different geometries for the recess 115 that is formed in the source/drain regions 92. In the embodiment depicted in FIG. 17D, the etch process produces a recess 115 having a base characterized by a U-shaped geometry, as viewed from a side cross-section. However, the etch parameters may be configured to provide for selective etching to the (111) planes of silicon. Under these conditions, the recess 115 may have a V-shaped like cavity that results from the slower etching rate of the silicon (111) planes, as depicted in FIG. 21. In yet another embodiment, the etch parameters may be configured so that the (111) facet is formed during etch due to the slowest etching rate of the (111) plane, which can result in a diamond shaped recess when viewed from a side cross-sectional view, as illustrate in FIG. 22. In yet an even further embodiment, the etch parameters may be configured so that the (111) facet is formed during etch due to the slowest etching rate of the (111) plane, which can result in an irregular shaped recess having a substantially flat base when viewed from a side cross-sectional view, as illustrate in FIG. 23. It is noted that the geometries for the recess 115 that is depicted in FIGS. 17D, 21, 22 and 23 are provided for illustrative purposes only, and are not intended to limit the present disclosure. The base of the recess 15 provides a contact surface for epitaxially forming a contact layer as depicted in FIG. 17E.

FIG. 17E illustrates an embodiment of epitaxially forming a contact layer 200 on the contact surface, wherein the contact layer 200 comprises a second composition and has a second concentration of the first conductivity type dopant, wherein the second concentration is greater than the first concentration for the first conductivity type dopant. For example, the second composition for the epitaxially formed contact layer 200 may have a base material of a type IV semiconductor, such as silicon and/or germanium. In some embodiments, the base material for the second composition for the epitaxially formed contact layer 200 maybe silicon germanium, in which the germanium content may range from 40 wt. % to 90 wt. %. The first conductivity type dopant for the contact layer 200 is the same conductivity type as the dopant for the source/drain regions 92. For example, the contact layer 200 may be doped with a p-type dopant, such as boron or gallium. As noted, the concentration for the p-type dopant in the contact layer 200 is greater than the concentration of the p-type dopant in the source/drain region 92. In some embodiments, the methods and structures described herein provide a low contact resistance contact to the epitaxial source/drain regions 92 by removing a portion of the low concentration doped epitaxial material of the source/drain regions 92 at the contact landing point for the metal contact to the source/drain region 92, and epitaxially forming a high-concentration doped contact layer 200 as the contact landing point for the metal contact to the source/drain region 92. For example, silicide landed on an epitaxially formed contact layer 200 (as depicted in FIG. 17E) having a high germanium concentration and a high concentration of p-type dopant, such as boron (B) and/or gallium (Ga), results in not only a lower Schottky barrier height between silicide and the p-type epitaxial semiconductor material of the source/drain region 92, but also higher carrier tunneling probability. As a result, the contact resistivity is low. In some embodiments, wherein the concentration (e.g., second concentration) of the first conductivity type dopant, such as a p-type dopant, e.g., boron and/or gallium, that is present in the contact layer 200 ranges from 1×10²⁰/cm³-1×10²²/cm³.

In some embodiments, epitaxially forming the contact layer 200 on the contact surface means the growth of a semiconductor material on a deposition surface of a semiconductor material, in which the semiconductor material being grown has substantially the same crystalline characteristics as the semiconductor material of the deposition surface, e.g., contact surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

A number of different sources may be used for the deposition of the semiconductor material that forms the contact layer 200. In some embodiments, in which the contact layer 200 is composed of silicon germanium (SiGe), the silicon gas source for epitaxial deposition may include at least one of silane (SiH₄), disilane (Si₂H₆), trisilane (Si₃H₈), hexachlorodisilane (Si2Cl₆), tetrachlorosilane (SiCl₄), dichlorosilane (Cl₂SiH₂), trichlorosilane (Cl₃SiH), methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄), hexamethyldisilane ((CH₃)₆Si₂) and combinations thereof. In some embodiments, the germanium gas source for epitaxial deposition of the contact layer 200 composed of silicon germanium may include at least one of germane (GeH₄), digermane (Ge₂H₆), germanium tetrachloride (GeCl₄), halogermane, dichlorogermane, trichlorogermane, tetrachlorogermane and combinations thereof. Further, in some embodiments, hydrochloric acid (HCl) may be employed as a precursor in selective growth processes.

In some embodiments, the dopant that dictates the conductivity type of the source/drain regions 92 is introduced in-situ. By “in-situ” it is meant that the dopant that dictates the conductivity type of the source/drain regions 92 is introduced during the process step, e.g., epitaxial deposition, that forms the source/drain regions 92. To provide a p-type dopant of boron, a source gas of diborane may be employed. In some embodiments, a precursor of boron trichloride (BCL₃) may provide the boron source. In some embodiments, the epitaxial deposition may be continued until a contact layer 200 is formed having a thickness ranging from 20 nm to 80 nm.

The contact layer 200 is formed directly on the contact surface of the source/drain regions 92 that is exposed by forming the recess 115. The contact layer 200 may be a conformal layer. For example, in some embodiments, the contact layer 200 is formed directly on a U-shaped contact surface of the recess 115, wherein the contact layer 200 has a U-shaped side cross-sectional geometry when viewed from a side cr0ss-sectional view, as illustrated in FIG. 17E. However, the contact layer 200 does not necessarily have to be a conformal layer. For example, the contact layer 200 may have a base surface with a V-shaped geometry when viewed from a side cross-sectional view, in which the thickness of the contact layer 200 is non-conformal, as illustrated in FIG. 21. Referring to FIG. 22, in another embodiment, the contact layer 200 may be formed having a base surface defined by five faces, which can be characterized as a diamond shaped cross-section with a flat bottom. FIG. 23 illustrates another embodiment of a non-conformal contact layer 200 having a flat base surface.

The upper surface of the contact layer 200 may have a U-shaped geometry when viewed from a side cross-section, as illustrated in FIGS. 17E, 17F, 18B, 19A, 19B, 20, 21, 22 and 23. The upper surface of the contact layer 200 provides the surface that is directly contacted by the metal for the metal contact 116 to the source/drain regions 92, wherein an interface between the metal of the metal contact 116 and the contact layer 200 includes a metal semiconductor alloy 205, e.g., silicide, that forms thereon, as illustrated in FIG. 17F.

FIG. 17F further illustrates the profile for the germanium concentration within the contact layer 200, and the profile for the p-type dopant, e.g., boron and/or gallium, in the contact layer 200. Depending upon the epitaxial deposition process conditions, the germanium concentration for the silicon germanium of the contact layer 200 may be constant or may have a gradient. Depending upon the epitaxial deposition process conditions, the p-type dopant concentration for the boron and/or gallium dopant of the contact layer 200 may be constant or may have a gradient.

For example, FIG. 17G illustrates the plot for one embodiment of the germanium concentration in wt. % as measured from point 1 in FIG. 17F to point 2 in FIG. 17F. The y-axis of FIG. 17G illustrates the germanium concentration of silicon germanium in the contact layer 200. The x-axis of FIG. 17G illustrates the depth at which the germanium concentration measurement is taken as measured from point 1 to point 2, which is a vertical height relative to the upper surface of the metal contact 116. Plot 301 of FIG. 17G illustrates that the germanium concentration within the silicon germanium of the contact layer 200 may be constant from the upper surface (point 1) of the contact layer 200 to the base surface (point 2) of the contact layer 200. For plot 301, the germanium concentration (Ge %) may range from 40% to 90%. Plot 302 of FIG. 17G illustrates that the germanium concentration within the silicon germanium of the contact layer 200 may be a gradient from the upper surface (point 1) of the contact layer 200 to the base surface (point 2) of the contact layer 200. For plot 302, the germanium concentration (Ge %) may range from 40% to 90%.

For example, FIG. 17H illustrates the plot for an embodiment of the germanium concentration in wt. % as measured from point 3 in FIG. 17F to point 4 in FIG. 17F. The y-axis of FIG. 17H illustrates the germanium concentration of silicon germanium in the contact layer 200. The x-axis of FIG. 17H illustrates the depth at which the germanium concentration measurement is taken as measured from point 3 to point 4, which is a horizontal width relative to the upper surface of the metal contact 116. Plot 303 of FIG. 17H illustrates that the germanium concentration within the silicon germanium of the contact layer 200 may be constant from the left side (point 3) of the contact layer 200 to the right side (point 4) of the contact layer 200. For plot 303, the germanium concentration (Ge %) may range from 40% to 90%. Plot 304 of FIG. 17H illustrates that the germanium concentration within the silicon germanium of the contact layer 200 may be a gradient from the left side (point 3) of the contact layer 200 to the right side (point 4) of the contact layer 200. For plot 304, the germanium concentration (Ge %) may range from 40% to 90%.

For example, FIG. 17I illustrates the plot for an embodiment of the p-type dopant concentration, e.g., concentration of boron and/or gallium, as measured from point 1 in FIG. 17I to point 2 in FIG. 17I. The y-axis of FIG. 17I illustrates the p-type dopant concentration of silicon germanium in the contact layer 200. The x-axis of FIG. 17I illustrates the depth at which the p-type dopant concentration measurement is taken as measured from point 1 to point 2, which is a vertical height relative to the upper surface of the metal contact 116. Plot 305 of FIG. 17I illustrates that the p-type dopant concentration within the silicon germanium of the contact layer 200 may be constant from the upper surface (point 1) of the contact layer 200 to the base surface (point 2) of the contact layer 200. For plot 305, the p-type dopant concentration may include boron (B) and gallium (Ga) having a concentration ranging from 1×10²⁰ atoms/cm³ to 1×10²² atoms/cm³. Plot 306 of FIG. 17I illustrates that the p-type dopant concentration within the silicon germanium of the contact layer 200 may be a gradient from the upper surface (point 1) of the contact layer 200 to the base surface (point 2) of the contact layer 200. For plot 306, the p-type dopant concentration may include boron (B) and gallium (Ga) having a concentration ranging from 1×10²⁰ atoms/cm³ to 1×10²² atoms/cm³.

For example, FIG. 17J illustrates the plot for an embodiment of the p-type dopant concentration, e.g., concentration of boron and/or gallium, as measured from point 3 in FIG. 17F to point 4 in FIG. 17F. The y-axis of FIG. 17J illustrates the p-type dopant concentration of silicon germanium in the contact layer 200. The x-axis of FIG. 17J illustrates the depth at which the p-type dopant concentration of silicon germanium is taken as measured from point 3 to point 4, which is a horizontal width relative to the upper surface of the metal contact 116. Plot 307 of FIG. 17J illustrates that the p-type dopant concentration of silicon germanium of the contact layer 200 may be constant from the left side (point 3) of the contact layer 200 to the right side (point 4) of the contact layer 200. For plot 307, the p-type dopant concentration may include boron (B) and gallium (Ga) having a concentration ranging from 1×10²⁰ atoms/cm³ to 1×10²² atoms/cm³. Plot 308 of FIG. 17J illustrates that the p-type dopant concentration within the silicon germanium of the contact layer 200 may be a gradient from the left side (point 3) of the contact layer 200 to the right side (point 4) of the contact layer 200. For plot 308, the p-type dopant concentration may include boron (B) and gallium (Ga) having a concentration ranging from 1×10²⁰ atoms/cm³ to 1×10²² atoms/cm³.

It is noted that the above described profiles for the germanium (Ge) concentration and p-type dopant concentration, such as boron (B) and gallium (Ga), that have been described above with reference to FIGS. 17G to 17J are provided for illustrative purposes only. It is not intended that the contact layer 200 described herein be limited to only these profiles, because other profiles are equally applicable to the methods and structures described herein.

FIGS. 18A and 18B illustrate some embodiments of forming gate contacts 114 to the gate structure and metal contacts 116 to the source/drain regions 92. FIG. 18A illustrates an embodiment of the gate contact 114 being formed to the gate conductor 102 of a gate structure. FIG. 18B illustrates an embodiment of forming a metal contact 116 to the contact layer 200 of the source/drain regions 92.

FIG. 18B illustrates an embodiment of depositing a metal on the contact layer 200, wherein a metal semiconductor alloy 205, e.g., silicide, is formed at an interface between the metal of the metal contact 116 and the contact layer 200. For example, the interface of the metal semiconductor alloy 205 can be formed by first depositing a metal for the metal contact 116 that is capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92 that are present in the recesses 115 forming into the source/drain regions 92.

In an embodiment, the metal semiconductor alloy 205 is a silicide, e.g., a silicide of TiSi, and has a thickness in a range between about 2 nm and about 10 nm. In this example, the metal semiconductor alloy 205 is formed during the deposition process that forms the metal contact 116. More specifically, the titanium silicide for the metal semiconductor alloy 205 is formed by depositing titanium using chemical vapor deposition (CVD). More particularly, using a chemical vapor deposition (CVD) tool during the deposition of the metal for the metal contact 116, the titanium precursor, e.g., titanium chloride (TiCl4), introduces titanium (Ti) that will react with silicon (Si) from the contact layer 200 to form the metal semiconductor alloy 205. In some embodiments, the chemical vapor deposition (CVD) process for forming the metal semiconductor alloy 205 and the metal contact 116 may include titanium chloride (TiCl4) deposition gas with a H2 (carrier gas). In some embodiments, the temperature for forming the metal semiconductor alloy 205 and the metal contact 116 may range from 350 °C 450 °C. It is noted that the temperature of the chemical vapor deposition (CVD) process is sufficient for forming the metal semiconductor alloy layer 205 of titanium silicide (TiSi) without additional annealing. The metal semiconductor alloy layer 205 may have a thickness ranging from 2 nm to 10 nm. The metal semiconductor alloy layer 205 when viewed from a side cross-sectional view may have a U-shaped geometry. The chemical vapor deposition (CVD) process may continue until the metal for the metal contact 116 fills the recess 115 that is formed in the source/drain region 92 and the fourth recess 112 that is formed through the first ILD 96 and the second ILD 106. During the process for forming the metal contact 116 to the source/drain regions 92, the metal for the gate contact 114 to the gate electrode 102 of the gate structure may also be formed. A planarization process, such as a CMP process, may be performed to remove excess material from a surface of the second ILD 106 that overflows during the process steps used to forming the gate contact 114 and the metal contact 116 to the source/drain regions 92.

In some embodiments, the method described above can be employed to provide a device including source/drain regions 92 having a first silicon containing base material composition and a first concentration of a p-type conductivity type dopant, wherein the source/drain regions 92 comprises a recessed contact surface (e.g., recess 115). In some embodiments, a contact layer 200 is on the recessed contact surface, wherein the contact layer 200 includes a second silicon containing composition and has a second concentration of the p-type conductivity type dopant, wherein the second concentration is greater than the first concentration for the p-type conductivity type dopant. The device may further include a metal contact 116 on the contact layer 200, wherein an interface layer (e.g., metal semiconductor alloy layer 205) is between the metal of the metal contact 116 and the contact layer 200. The interface layer may be composed of a metal semiconductor alloy 205, such as titanium silicide (TiSi).

In some embodiments, the methods and structures described herein provide a low contact resistance contact, e.g., metal contact 116, to the epitaxial source/drain regions 92 by removing a portion of the low concentration doped epitaxial material of the source/drain regions 92 at the contact landing point for the metal contact to the source/drain region 92, and epitaxially forming a high-concentration doped contact layer 200 as the contact landing point for the metal contact 116 to the source/drain region 92. For example, a metal semiconductor alloy 205, e.g., titanium silicide, landed on an epitaxially formed contact layer 200 having a high germanium concentration and a high concentration of p-type dopant, such as boron (B) and/or gallium (Ga), results in not only a lower Schottky barrier height between silicide and the p-type epitaxial semiconductor material of the source/drain region 92, but also higher carrier tunneling probability. As a result, the contact resistivity of the metal contact 116 to the source/drain regions 92 is low.

In some embodiments, the contact layer 200 is formed after the source/drain regions 92 (including the first semiconductor material 92a, second semiconductor material 92b and third semiconductor material 92c), and the contact etch step layer (CESL) 94. The contact layer 200 is also formed after the interlevel dielectric layer (ILD) 96. More specifically, in some embodiments, the contact layer 200 is formed through an opening passing through contact etch stop layer (CESL) 94 and the interlevel dielectric layer (ILD) 96. In some embodiments, because the contact layer 200 is formed in an opening through the contact etch stop layer (CESL) 94 and the interlevel dielectric layer (ILD) 96, the contact layer 200 will not be covered/overlaid by the contact etch stop layer (CESL) 94 and the interlevel dielectric layer (ILD) 96. Although a portion of the contact etch stop layer (CESL) 94 and the interlevel dielectric layer (ILD) 96 is removed in forming the opening that the contact layer 200 is formed in, a remaining portion of the contact etch stop layer (CESL) 94 and the interlevel dielectric layer (ILD) 96 is present over portions of the source/drain regions 92. For example, a portion of the contact etch stop layer (CESL) 94 and the interlevel dielectric layer (ILD) 96 is present over the first semiconductor layer 92a, second semiconductor layer 92b and third semiconductor layer 92c of the source/drain region 92.

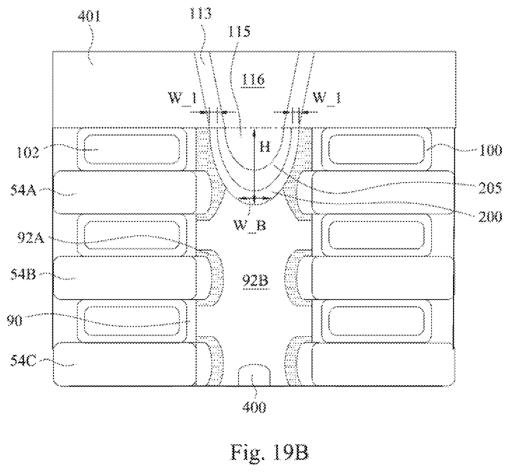

The aforementioned metal contacts 116 are formed from a front side, e.g., top side, of the device. In these examples, the metal contacts 116 are formed through interlevel dielectrics, such as the first ILD 96 and the second ILD 106, that are formed atop the source/drain region 92, in which the source/drain regions 92 are formed over the substrate 50. It is noted that the metal contacts 116, the metal semiconductor alloy 205 and the contact layer 200 are not limited to only frontside applications. For example, FIGS. 19A-23 illustrate some embodiments in which the metal contacts 116 are formed to a contact layer 200 of source/drain regions 92 from the backside of the device. More particularly, the source/drain regions 92 may be formed through dielectrics that are formed in the space previously occupied by the device's substrate 50. In some embodiments, in a backside process, after the transistor layer has been formed, which includes the nanostructures 55, the source/drain regions 92 and the gate structure, the front side contacts 400 may be formed. Then in a subsequent process, a carrier substrate is bonded to the frontside of the device, e.g., to the frontside interconnect. With the carrier substrate engaged, the structure is then car flipped, and then some or all of the substrate is removed. At this point, backside interconnects may be formed to the source/drain regions 92. The backside interconnects are illustrated in FIGS. 19A-23 by reference number 116. The backside interconnects (metal contacts 116) to the source/drain regions 92 are similar to the metal contacts 116 to the source/drain regions 92 that are formed from the frontside of the device. Therefore, the above description of elements having the reference numbers in FIGS. 1-18B are suitable for providing the description of elements having the same reference numbers in FIGS. 19A-23. It is noted that although the backside interconnects (metal contacts 116) depicted in FIGS. 19A-23 are formed from the backside of the device, the structures illustrated in FIGS. 19A-23 place the backside of the device towards the top of the page. Further, reference number 401 represents a remaining portion of the substrate following backside processing, or a backside dielectric layer that is formed after the entirety of the original substrate is removed during backside processing.

FIGS. 19A and 19B illustrate one embodiment of a U-Shaped contact layer 200 as employed for a backside contact layer. Opposite the metal contact 116 for the backside contact, is a frontside contact 400 that is in electrical contact with an opposite side of the source/drain region 92. More particularly, the metal contact 116 for the backside contact is present at a backside of the device, and the frontside contact 400 is present directly contacting a top side of the source/drain 92 at the front side/top side of the structure. Referring to FIG. 19B, in some embodiments, the height H that extends from the interface of the contact layer 200 and the source/drain 92 to the top of the recess 115 that is coplanar with the base of the backside substrate 401 may range from 0.5 nm to 40 nm. In some embodiments, the first width W_1 of the contact layer 200 at the interface with the backside substrate 401 may range from 0 nm to 15 nm. In some embodiments, the second width (e.g., base width) W_B for the contact layer 200 may range from 0 nm to 30 nm.

FIG. 20 illustrates one embodiment of metal contact 116 formed at the backside of the device, in which the metal contact 116 contacts a U-shaped contact layer 200, which is similar to the contact structure depicted in FIGS. 19A and 19B. However, the structure depicted in FIG. 20 further includes a bottom dielectric layer 230 between the protective spacer 113 and the backside substrate 401 and the metal semiconductor alloy 205, and the contact layer 200. The bottom dielectric layer 230 may be a nitride, such as silicon nitride. The bottom dielectric layer 230 also separates the backside substrate 401 from the source/drain region 92.

FIG. 21 illustrates one embodiment of a metal contact 116 formed at the backside of the device, in which the metal contact 116 contacts a contact layer 200 having a V-shaped geometry when viewed from a side cross-section. The contact layer 200 has a higher concentration of p-type dopant than the epitaxial material of the source/drain region 92 that the contact layer 200 is in contact with. Similar to the embodiments described with reference to FIGS. 19A-20, the source/drain 92 may also include a frontside contact 400.

The V-shaped epitaxial material for the contact layer 200 may result from differential etching condition applied to the epitaxial material of the source/drain region 92 to form the recess 115 that the contact layer 200 is formed in. In some embodiments, the differential etching can cause intensive etching that can increase the height (H) of cavity. Further, the V-shape geometry for the cavity may result from the slower etching rate of silicon (111) planes.

Referring to FIG. 21, in some embodiments, the height H that extends from the apex of the interface of the V-shaped contact layer 200 with the source/drain 92 to the top of the recess 115 that is coplanar with the base of the backside substrate 401 may range from 0.5 nm to 40 nm. In some embodiments, the first width W_1 of the V-shaped contact layer 200 at the interface with the backside substrate 401 may range from 0 nm to 15 nm. In some embodiments, the angle A defined by the sidewall of the apex portion of the base surface of the V-shaped contact layer 200 relative to horizontal may range from 30-80°.

It is noted that the V-shaped contact layer 200 is not limited to only backside type contacts. The V-shaped contact layer 200 may be equally applicable to frontside type contacts to the source/drain regions 92.

FIG. 22 illustrates one embodiment of a metal contact 116 formed at the backside of the device, in which the metal contact 116 contacts a contact layer 200 having a diamond-shaped geometry when viewed from a side cross-section. The contact layer 200 has a higher concentration of p-type dopant than the epitaxial material of the source/drain region 92 that the contact layer 200 is in contact with. Similar to the embodiments described with reference to FIGS. 19A-21, the source/drain 92 may also include a frontside contact 400.

In some embodiments, the diamond shape of the epitaxial material for the contact layer 200 may be formed using selective etching for forming (111) facets in silicon. The (111) fact of silicon may have the slowest etching rate for the epitaxial material of the source/drain region 92. The contact layer 200 is epitaxially formed in the recess 115 defined by the aforementioned facets. Preferential etching in this manner can result in recess on which the diamond shape epitaxial material is deposited for the contact layer 200. The contact layer 200 has a higher concentration of p-type dopant than the epitaxial material of the source/drain region 92 that the contact layer 200 is in contact with. Similar to the embodiments described with reference to FIGS. 19A-21, the source/drain 92 may also include a frontside contact 400.

Referring to FIG. 22, in some embodiments, the height H that extends from the base of the interface of the diamond shaped contact layer 200 with the source/drain 92 to the top of the recess 115 that is coplanar with the base of the backside substrate 401 may range from 0.5 nm to 40 nm. In some embodiments, the first width W_1 of the diamond shaped contact layer 200 at the interface with the backside substrate 401 may range from 0 nm to 15 nm. In some embodiments, the second width W_2 of the diamond shaped contact layer 200 at the mid-height of the diamond shaped contact layer 200 may range from 1 nm to 15 nm. In some embodiments, the third width (e.g., base width) W_B for the contact layer 200 may range from 1 nm to 30 nm.

It is noted that the diamond shaped contact layer 200 is not limited to only backside type contacts. The diamond shaped contact layer 200 may be equally applicable to frontside type contacts to the source/drain regions 92.

FIG. 23 illustrates one embodiment of a metal contact 116 formed at the backside of the device, in which the metal contact 116 contacts a contact layer 200 having an irregular geometry with a flat when viewed from a side cross-section. The contact layer 200 has a higher concentration of p-type dopant than the epitaxial material of the source/drain region 92 that the contact layer 200 is in contact with. Similar to the embodiments described with reference to FIGS. 19A-22, the source/drain 92 may also include a frontside contact 400.

Referring to FIG. 23, in some embodiments, the height H that extends from the base of the interface irregular shaped contact layer 200 with the source/drain 92 to the top of the recess 115 that is coplanar with the base of the backside substrate 401 may range from 0.5 nm to 40 nm. In some embodiments, the first width W_1 of the irregular shaped contact layer 200 at the interface with the backside substrate 401 may range from 0.5 nm to 15 nm. In some embodiments, the second width W_2 of the irregular shaped contact layer 200 at the mid-height of the irregular shaped contact layer 200 may range from 1 nm to 15 nm. In some embodiments, the third width (e.g., base width) W_B for the contact layer 200 may range from 1 nm to 30 nm.

In some embodiments, the angle A2 defined by the intersection of the sidewall of the irregular shaped contact layer 200 that abuts the first semiconductor material layer 92A of the source/drain regions 92, and the base surface of the irregular shaped contact layer 200 with the second semiconductor material layer 92B of the source/drain regions 92 may range from 30-80°.

It is noted that the irregular shaped contact layer 200 is not limited to only backside type contacts. The irregular shaped contact layer 200 may be equally applicable to frontside type contacts to the source/drain regions 92.

In an embodiment, a method is described comprising: forming a source/drain region having a first base material composition and a first concentration of a first conductivity type dopant; removing a portion of the source/drain region having the first base material composition and the first concentration of the first conductivity type dopant to expose a contact surface; epitaxially forming a contact layer on the contact surface, wherein the contact layer comprises a second composition and has a second concentration of the first conductivity type dopant, wherein the second concentration is greater than the first concentration for the first conductivity type dopant; and depositing a metal on the contact layer, wherein an interface between the metal and the contact layer comprise a metal semiconductor alloy. In an embodiment, the first base material is a type IV semiconductor. In an embodiment, the type IV semiconductor comprises silicon and germanium. In an embodiment, the first conductivity type dopant is a p-type dopant. In an embodiment, the p-type dopant comprises boron or gallium. In an embodiment, the first concentration of the first conductivity type dopant ranges from 8×10¹⁹ atoms/cm³ to 1×10²¹ atoms/cm³.

In an embodiment, the contact layer has a U-shaped geometry when viewed from a side cross-sectional view. In an embodiment, the removing the portion of the source/drain region having the first base material composition and the first concentration of the first conductivity type dopant to expose the contact surface comprise an etch that is selective to the (111) planes of a silicon containing composition for the first base material composition. In an embodiment, the contact surface includes (111) facets and has a V-shaped geometry or a diamond shaped geometry when viewed from a side cross-section.

In an embodiment, a semiconductor device comprising: a plurality of channel layers vertically stacked; a source/drain region adjacent to the plurality of channel layers; an interlevel dielectric layer over the source/drain region; and a conductive contact extending through the interlevel dielectric layer and electrically coupled to the source/drain region, wherein the source/drain region comprises: a first semiconductor material layer having a first p-type dopant concentration; and a second semiconductor material layer on the first semiconductor material layer having a second p-type dopant concentration, the second p-type dopant concentration being greater than the first p-type dopant concentration; a contact layer on and extending into the first and second semiconductor materials, the contact layer comprising a germanium-containing material and having a third p-type dopant concentration greater than the first and second p-type dopant concentrations, wherein the contact layer contacts the first semiconductor material layer along sidewalls of the contact layer and contacts the second semiconductor material layer at a base of the contact layer. In an embodiment, the semiconductor device further includes a metal semiconductor alloy layer between the contact layer and the conductive contact. In an embodiment, a composition for the second semiconductor material includes germanium is a concentration ranging from 20 wt. % to 60 wt. %, a p-type dopant for the first p-type concentration is boron, and the first p-type concentration ranges from 8×10¹⁹ atoms/cm³ to 1×10²¹ atoms/cm³. In an embodiment, a composition for the contact layer includes germanium in a concentration ranging from 40 wt. % to 90 wt. %, a p-type dopant for the third p-type dopant concentration is boron, and the third p-type dopant concentration ranges from 1×10²⁰ atoms/cm³ to 1×10²² atoms/cm³. In an embodiment, the contact layer has a U-shaped geometry when viewed from a side cross-sectional view. In an embodiment, the contact layer has a V-shaped geometry or a diamond shaped geometry when viewed from a side cross-section.

In an embodiment, a method comprising: forming source/drain regions adjacent a plurality of nanosheets, wherein the source/drain region comprise a first semiconductor material layer having a first p-type dopant concentration, and a second semiconductor material layer on the first semiconductor material layer having a second p-type dopant concentration, the second p-type dopant concentration being greater than the first p-type dopant concentration; forming an interlevel dielectric layer on the source/drain regions having a contact via opening to the source/drain regions; removing a portion of the source/drain region within the contact via opening to expose a contact surface; epitaxially forming a contact layer on the contact surface, the contact layer comprising a germanium-containing material and having a third p-type dopant concentration greater than the first and second p-type dopant concentrations, wherein the contact layer contacts the first semiconductor material layer along sidewalls of the contact layer and contacts the second semiconductor material layer at a base of the contact layer; and depositing a metal on the contact layer, wherein an interface between the metal and the contact layer comprise a metal semiconductor alloy. In an embodiment, a composition for the second semiconductor material includes germanium is a concentration ranging from 20 wt. % to 60 wt. %, a p-type dopant for the first p-type concentration is boron, and the first p-type concentration ranges from 8×10¹⁹ atoms/cm³ to 1×10²¹ atoms/cm³. In an embodiment, a composition for the contact layer includes germanium in a concentration ranging from 40 wt. % to 90 wt. %, a p-type dopant for the third p-type dopant concentration is boron, and the third p-type dopant concentration ranges from 1×10²⁰ atoms/cm³ to 1×10²² atoms/cm³.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a source/drain region adjoining a channel region;
depositing an interlayer dielectric (ILD) over the source/drain region;
patterning an opening through the ILD, wherein the opening extends partially into the source/drain region;
forming a semiconductor material through the opening on an exposed surface of the source/drain region, wherein the semiconductor material has a higher germanium concentration than the source/drain region; and
forming a source/drain contact in the opening.

2. The method of claim 1, wherein an impurity concentration of the semiconductor material is greater than an impurity concentration of the source/drain region.

3. The method of claim 1 further comprising forming a silicide region on a top surface of the semiconductor material, wherein the source/drain contact is electrically coupled to the source/drain region through the silicide region and the semiconductor material.

4. The method of claim 1, wherein patterning the opening comprises removing an upper portion of the source/drain region using an etching process that selectively etches (111) plane facets at a slower rate.

5. The method of claim 1, wherein a germanium concentration of the semiconductor material is in a range of 40 wt. % to 90 wt. %.

6. The method of claim 1, wherein a bottom surface of the opening is substantially flat.

7. The method of claim 1, wherein a bottom of the opening in the source/drain region is V-shaped.

8. The method of claim 1, wherein a bottom of the opening in the source/drain region is U-shaped.

9. The method of claim 1 further comprising forming insulating spacers on sidewalls of the opening prior to forming the semiconductor material.

10. A method comprising:
patterning a source/drain recess extending through a stack of nanostructures;
epitaxially growing a source/drain region in the source/drain recess;
forming a gate structure around the stack of nanostructures;
after forming the gate structure, removing a portion of the source/drain region;
epitaxially growing a semiconductor material on a remaining portion of the source/drain region, wherein epitaxially growing the semiconductor material comprises doping the semiconductor material to have a higher dopant concentration than the source/drain region;
forming a silicide region on the semiconductor material; and
forming a source/drain contact electrically connected to the source/drain region through the silicide region and the semiconductor material.

11. The method of claim 10, wherein the semiconductor material has a higher p-type dopant concentration than the source/drain region.

12. The method of claim 10, wherein the semiconductor material has a higher germanium concentration than the source/drain region.

13. The method of claim 10, wherein the portion of the source/drain region that is removed is at a front-side of the source/drain region.

14. The method of claim 10, wherein the portion of the source/drain region that is removed is at a backside of the source/drain region.

15. A structure comprising:
a plurality of nanostructures;
a source/drain region adjoining the plurality of nanostructures;
a gate structure surrounding the plurality of nanostructures;
a semiconductor material embedded in the source/drain region, wherein the semiconductor material has a higher germanium concentration and a higher p-type dopant concentration than the source/drain region;
a silicide region on the semiconductor material; and
a source/drain contact electrically connected to the source/drain region through the silicide region and the semiconductor material.

16. The structure of claim 15, wherein a germanium concentration in the semiconductor material decreases from a mid-point between top and bottom surfaces of the semiconductor material in a direction towards the source/drain region.

17. The structure of claim 15, wherein a germanium concentration in the semiconductor material increases from a sidewall of the semiconductor material towards a center of the semiconductor material.

18. The structure of claim 15, wherein the source/drain contact extends into the source/drain region.

19. The structure of claim 15, wherein a p-type dopant concentration in the semiconductor material decreases from a mid-point between top and bottom surfaces of the semiconductor material in a direction towards the source/drain region.

20. The structure of claim 15, wherein a p-type dopant concentration in the semiconductor material increases from a sidewall of the semiconductor material towards a center of the semiconductor material.
